(19) United States
(12) Patent Application Publication
(10) Pub. No.: US 2008/0061452 A1
(43) Pub. Date: Mar. 13, 2008

(54) Bonded wafer and method of manufacturing the same

(75) Inventors: Hideki NISHIHATA, Yamagata (JP); Nobuyuki MORIMOTO, Yamagata (JP); Akihiko ENDO, Yamagata (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 11/851,065

(22) Filed: Sep. 6, 2007

(30) Foreign Application Priority Data
Sep. 7, 2006 (JP) 242376/2006

(51) Int. Cl. H01L 21/30; H01L 23/58

(52) U.S. Cl. 257/798; 438/459; 257/E21.087

(57) ABSTRACT

The present invention provides a method of manufacturing a bonded wafer. When bonding the top wafer through an insulating film exceeding about 1,000 Angstroms in thickness to the base wafer, a top wafer and a base wafer in which the total number of particles having a size of equal to or greater than about 0.20 micrometers present on the two surfaces being bonded is equal to or less than about 0.014 particles/cm² are bonded; and when bonding the top wafer through an insulating film having a thickness of equal to or less than about 1,000 Angstroms to the base wafer, or with no insulating film present between the top wafer and the base wafer, a top wafer and a base wafer are bonded wherein the total number of particles having a size of equal to or greater than about 0.20 micrometers present on the two surfaces being bonded is equal to or less than about 0.007 particles/cm².

### CROSS-REFERENCE TO RELATED APPLICATIONS

This application claims the benefit of priority under 35 USC 119 to Japanese Patent Application No. 2006-242376 filed on Sep. 7, 2006, which is expressly incorporated herein by reference in its entirety.

### BACKGROUND OF THE INVENTION

1. Field of the Invention

The present invention relates to a bonded wafer and a method for manufacturing the same.

2. Discussion of the Background

Silicon-on-insulation (SOI) wafers afford advantages over conventional silicon wafers in the form of reduced separation between elements, reduced parasitic capacitance between elements and the substrate, and the possibility of forming three-dimensional structures. Utilizing these advantages, SOI wafers have been employed in high-speed, power-efficient LSIs and the like in recent years.

In one method for manufacturing SOI wafers, the ion implantation separation method (also called the Smart-Cut Method™), an ion-implantation layer is formed in a silicon wafer, two wafers are bonded together, and a heat treatment for separation is conducted to effect separation at the ion implantation layer as boundary. Such a method is described, for example, in Japanese Unexamined Patent Publication (KOKAI) Heisei No. 5-211128, or English language family member U.S. Pat. No. 5,374,564, which are expressly incorporated herein by reference in their entirety.

In conventional SOI wafers, two wafers are bonded together through a relatively thick insulating film (of about 1,500 Angstroms, for example). In recent years, demand has also been growing for SOI wafers for use in new devices, having a thin insulating film and a DSB (Direct Silicon Bonding) wafers manufactured by directly bonding two wafers without an insulating film between them. However, numerous defects known as voids (unbonded portions of the adhesion boundary face) have been generated in these bonded wafers for use in new devices, creating a problem of compromising device characteristics.

### SUMMARY OF THE INVENTION

An aspect of the present invention provides for a high-quality bonded wafer with few void defects.

The present inventors conducted extensive research into the causes of void defects to achieve the above-stated object. As a result, they discovered that particles of about 0.20 micrometers or greater in size that were present on the surfaces being bonded were the cause of the void defects especially in SOI wafers having a thin insulating film and the cause of defects in DSB wafers. Further research was conducted based on this discovery, and the present invention was devised on this basis.

An aspect of the present invention relates to a method of manufacturing a bonded wafer comprising:

bonding a top wafer and a base wafer to form a bonded wafer, and

thinning the top wafer comprised in the bonded wader,

wherein, in the bonding,

when bonding the top wafer through an insulating film exceeding about 1,000 Angstroms in thickness to the base wafer, a top wafer and a base wafer are bonded wherein the total number of particles having a size of equal to or greater than about 0.20 micrometers present on the two surfaces being bonded is equal to or less than about 0.014 particles/cm²; and

when bonding the top wafer through an insulating film having a thickness of equal to or less than about 1,000 Angstroms to the base wafer, or with no insulating film present between the top wafer and the base wafer, a top wafer and a base wafer in which the total number of particles having a size of equal to or greater than about 0.20 micrometers present on the two surfaces being bonded is equal to or less than about 0.007 particles/cm² are bonded.

In the bonding, the top wafer may be bonded to the base wafer through an insulating film having a thickness of equal to or less than about 500 Angstroms or with no insulating film present between the top wafer and the base wafer.

Both of the two surfaces being bonded in the bonding may have a surface roughness, RMS, of equal to or less than about 10 Angstroms.

The thinning may be conducted by, prior to the bonding, implanting light element ions into a top wafer to form an ion implantation layer in the top wafer, and following the bonding, subjecting the bonded wafer to heat treatment to separate a portion of the top wafer from the bonded wafer at the ion implantation layer as boundary.

A further aspect of the present invention relates to a method of manufacturing a bonded wafer comprising:

selecting at least one combination of a top wafer and a base wafer from a top wafer lot comprising a plurality of top wafers and a base wafer lot comprising a plurality of base wafers,

bonding the selected combination of a top wafer and a base wafer to form a bonded wafer, and

thinning the top wafer comprised in the bonded wafer,

wherein, in the selecting,

when the total thickness of an insulating film present on the two surfaces to be bonded exceeds about 1,000 Angstroms, a combination of a top wafer and a base wafer in which the total number of particles having a size of equal to or greater than about 0.20 micrometers on the two surfaces to be bonded is equal to or less than about 0.014 particles/cm² is selected; and

when the total thickness of an insulating film present on the two surfaces to be bonded is equal to less than about 1,000 Angstroms, or when no insulating film is present on the two surfaces to be bonded, a combination of a top wafer and a base wafer in which the total number of particles having a size of equal to or greater than about 0.20 micrometers on the two surfaces to be bonded is equal to or less than about 0.007 particles/cm² is selected.

The above method may further comprise:

extracting at least a portion of top wafers and base wafers that have not been selected in said selecting,

washing the extracted wafers, and

re-selecting at least one combination of a top wafer and a base wafer from wafers that have been subjected to the washing, or wafers that have been subjected to the washing and wafers that have not been subjected to the washing,

bonding the combination of a top wafer and a base wafer selected in the re-selecting to form a bonded wafer, and

thinning the top wafer comprised in the bonded wafer,

wherein, in the re-selecting,

when the total thickness of an insulating film present on the two surfaces to be bonded exceeds about 1,000 Angstroms, a combination of a top wafer and a base wafer in which the total number of particles having a size of equal to or greater than about 0.20 micrometers on the two surfaces to be bonded is equal to or less than about 0.014 particles/cm² is selected; and

when the total thickness of an insulating film present on the two surfaces to be bonded is equal to less than about 1,000 Angstroms, or when no insulating film is present on the two surfaces to be bonded, a combination of a top wafer and a base wafer in which the total number of particles having a size of equal to or greater than about 0.20 micrometers on the two surfaces to be bonded is equal to or less than about 0.007 particles/cm² is selected.

The washing may be conducted so as to obtain a washed wafer comprising a surface to be bonded when the washed wafer is subjected to the bonding having a surface roughness, RMS, of equal to or less than about 10 Angstroms.

In the bonding, the top wafer may be bonded to the base wafer through an insulating film having a thickness of equal to or less than about 500 Angstroms or with no insulating film present between the top wafer and the base wafer.

Both of the two surfaces being bonded in the bonding may have a surface roughness, RMS, of equal to or less than about 10 Angstroms.

In one embodiment, the thinning is conducted by, prior to the bonding, implanting light element ions into a top wafer to form an ion implantation layer in the top wafer, and following the bonding, subjecting the bonded wafer to heat treatment to separate a portion of the top wafer from the bonded wafer at the ion implantation layer as boundary.

A further aspect of the present invention relates to a bonded wafer manufactured by the method of manufacturing a bonded wafer of the present invention.

According to the present invention, voids generated in the bonding step and in the step of thinning the top wafer can be reduced, thereby providing a high-quality bonded wafer.

Other exemplary embodiments and advantages of the present invention may be ascertained by reviewing the present disclosure and the accompanying drawings.

### BRIEF DESCRIPTION OF THE DRAWINGS

The present invention will be described in the following text by the exemplary, non-limiting embodiments shown in the figures, wherein:

FIG. 1 shows the probability (expressed as a defect occurrence rate) that a particle of prescribed size adhered to the wafer surface prior to bonding will become the starting point of a void defect.

FIG. 2 is a drawing descriptive of the steps of manufacturing a bonded wafer.

### DESCRIPTIONS OF THE EMBODIMENTS

The following preferred specific embodiments are, therefore, to be construed as merely illustrative, and non-limiting to the remainder of the disclosure in any way whatsoever. In this regard, no attempt is made to show structural details of the present invention in more detail than is necessary for fundamental understanding of the present invention; the description taken with the drawings making apparent to those skilled in the art how several forms of the present invention may be embodied in practice.

According to an aspect of the present invention, the following two methods are provided for manufacturing a bonded wafer.

### Method I

A method of manufacturing a bonded wafer comprising:

bonding a top wafer and a base wafer to form a bonded wafer, and

thinning the top wafer comprised in the bonded wader,

wherein, in the bonding,

when bonding the top wafer through an insulating film exceeding 1,000 Angstroms in thickness to the base wafer, a top wafer and a base wafer are bonded wherein the total number of particles having a size of equal to or greater than 0.20 micrometers present on the two surfaces being bonded is equal to or less than 0.014 particles/cm²; and

when bonding the top wafer through an insulating film having a thickness of equal to or less than 1,000 Angstroms to the base wafer, or with no insulating film present between the top wafer and the base wafer, a top wafer and a base wafer are bonded wherein the total number of particles having a size of equal to or greater than 0.20 micrometers present on the two surfaces being bonded is equal to or less than 0.007 particles/cm².

### Method II

A method of manufacturing a bonded wafer comprising:

selecting at least one combination of a top wafer and a base wafer from a top wafer lot comprised of plural top wafers and a base wafer lot comprised of plural base wafers,

bonding the selected combination of a top wafer and a base wafer to form a bonded wafer, and

thinning the top wafer comprised in the bonded wafer,

wherein, in the selecting,

when the total thickness of an insulating film present on the two surfaces to be bonded exceeds 1,000 Angstroms, a combination of a top wafer and a base wafer in which the total number of particles having a size of equal to or greater than 0.20 micrometers on the two surfaces to be bonded is equal to or less than 0.014 particles/cm² is selected; and

when the total thickness of an insulating film present on the two surfaces to be bonded is equal to less than 1,000 Angstroms, or when no insulating film is present on the two surfaces to be bonded, a combination of a top wafer and a base wafer in which the total number of particles having a size of equal to or greater than 0.20 micrometers on the two surfaces to be bonded is equal to or less than 0.007 particles/cm² is selected.

Methods I and II will be described in detail below. In some instances, Methods I and II are collectively referred to as the “method of manufacturing a bonded wafer of the present invention.”

It has previously been pointed out that particles present on surfaces being bonded cause void defects. However, the complete elimination of particles from the wafer surfaces requires an extremely advanced degree of cleaning technology, renders the process complex, and increases manufacturing costs.

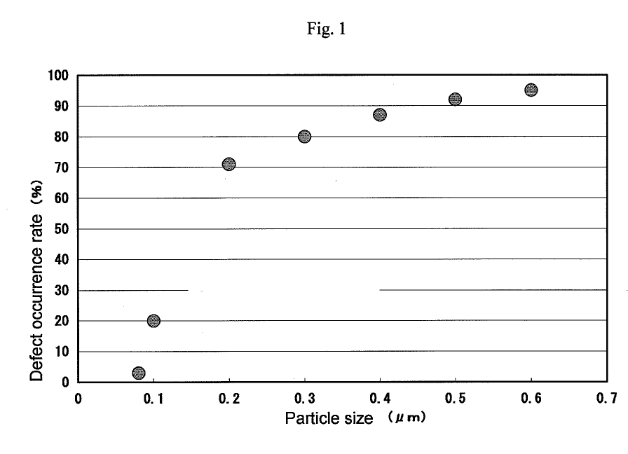

By contrast, extensive research conducted by the present inventors has revealed for the first time that the particles that are the major causes of void defects are 0.20 micrometers or greater in size. FIG. 1 shows the probability (expressed in terms of defect occurrence rate) that particles of a prescribed size that have adhered to the wafer surface prior to bonding will become the starting points of void defects in bonded wafers obtained by bonding a top wafer having an ion implantation layer with an ordinary base wafer, without an oxide film between the two, and then separating a portion of the top wafer at the ion implantation layer. As shown in FIG. 1, the probability of particles less than 0.20 micrometers becoming the starting points of void defects is equal to or less than 20 percent. By contrast, this probability is equal to or greater than 70 percent for particles of equal to or greater than 0.20 micrometer. The fact that, whether or not a particle will be a major cause of a void defect can be determined based on a size limit, was completely unknown in the past, and is being disclosed for the first time in the present invention. As the result of further research, it has also been determined that the thinner the oxide film present between the two wafers, the higher the probability that a particle present on the bonded surface will become a void defect.

Accordingly, based on the above discoveries, the present inventors further discovered that by regulating the total number of particles having a size of equal to or greater than 0.20 micrometers based on the thickness of the insulating film present at the bonding interface, it was possible to obtain a bonded wafer in which the occurrence of void defects was prevented or markedly reduced. The present invention was devised on this basis.

In the method of manufacturing a bonded wafer of the present invention, based on the above discoveries, when bonding a top wafer through an insulating film exceeding 1,000 Angstroms in thickness to a base wafer, a top wafer and a base wafer are bonded wherein the total number of particles having a size of equal to or greater than 0.20 micrometers present on the two surfaces being bonded is equal to or less than 0.014 particles/cm²; and when bonding a top wafer through an insulating film having a thickness of equal to or less than 1,000 Angstroms to a base wafer, or with no insulating film present between the top wafer and the base wafer, a top wafer and a base wafer are bonded wherein the total number of particles having a size of equal to or greater than 0.20 micrometers present on the two surfaces being bonded is equal to or less than 0.007 particles/cm². Further, since the probability is high of particles becoming void defects when conducting bonding with an insulating film that is particularly thin (for example, when the insulating film is equal to or less than 50 Angstroms in thickness), or without an insulating film, it is desirable to bond a combination of a top wafer and a base wafer in which the total number of particles having a size of equal to or greater than 0.20 micrometers on the two surfaces being bonded is equal to or less than 0.004 particles/cm². The reason why the probability of a particle becoming a void defect increases as the thickness of the insulating film decreases has not yet been determined. However, it is thought that when wafers are bonded through a relatively thick insulating film, the insulating film functions as a cushion. The above total number of particles is optimally 0 particles/cm². In the present invention, the term, “particle size” refers to the particle diameter as identified by a device measuring particles on the surface of a wafer. In the present invention, the phrase, “the total number of particles having a size of equal to or greater than 0.20 micrometers” is the value obtained by dividing the total number of particles having a size of equal to or greater than 0.20 micrometers on the two surfaces being bonded by the total area of the two surfaces being bonded, expressed as a number per unit area (per cm²).

In Method I, when bonding a top wafer through an insulating film exceeding 1,000 Angstroms in thickness to a base wafer, a top wafer and a base wafer are bonded wherein the total number of particles having a size of equal to or greater than 0.20 micrometers present on the two surfaces being bonded is equal to or less than 0.014 particles/cm²; and when bonding a top wafer through an insulating film having a thickness of equal to or less than 1,000 Angstroms to the base wafer, or with no insulating film present between the top wafer and the base wafer, a top wafer and a base wafer are bonded wherein the total number of particles having a size of equal to or greater than 0.20 micrometers present on the two surfaces being bonded is equal to or less than 0.007 particles/cm². Vigorous washing is an example of a method for reducing the total number of particles mentioned above. Normally, a clean wafer is employed as a base wafer, and a wafer in which particles have adhered to the surface during an ion implantation step and the like is often employed as a top wafer. Therefore, it is desirable to primarily heighten washing of the top wafer. Examples of washing methods are those commonly employed to wash wafers, such as washing with SC-1 (NH₄OH, H₂O₂, H₂O), washing with SC-1 (NH₄OH, H₂O₂, H₂O)+SC-2 (HCl, H₂O₂, H₂O), washing with HF/O₃, and washing with HF+O₃.

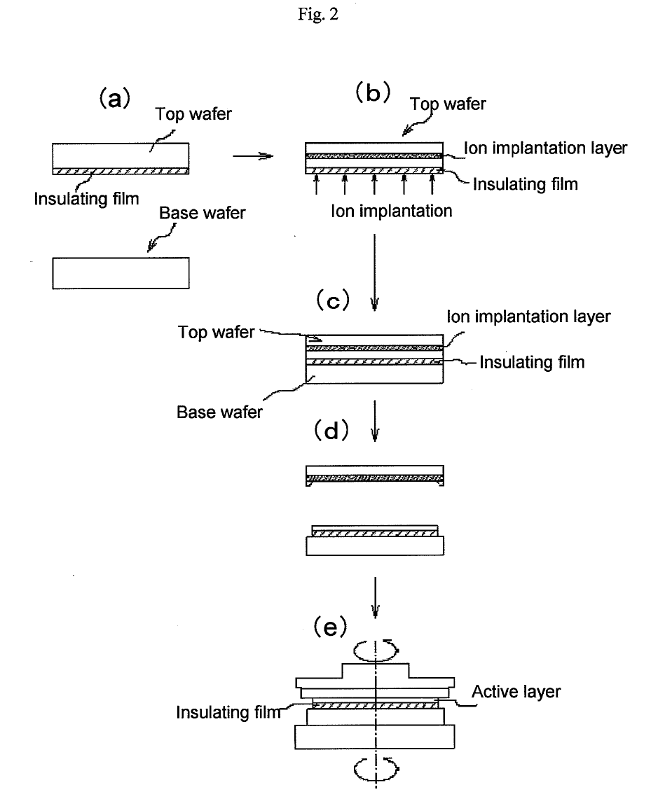

An embodiment of Method I will be specifically described below based on FIG. 2. However, the present invention is not limited to the embodiment described below.

First, two wafers are prepared for bonding. Next, the two wafers are polished to mirror surfaces using methods known in the art. When bonding is being conducted through an insulating film, the wafers being bonded may be in the form of, for example, two silicon wafers sliced from a single silicon ingot that has been grown by the CZ method or the like and doped with boron. When directly bonding two wafers without an insulating film between them, a silicon wafer may be employed as the base wafer and a wafer that is heterogeneous with the base wafer may be employed as the top wafer, or a silicon wafer of different orientation from the base wafer may be employed. In the present invention, the direct bonding of two wafers without an insulating film between them means that the two wafers are bonded without intentionally forming an insulating layer present between them, and includes the case where two wafers are bonded through a natural oxide film.

When bonding two wafers through an insulating film, an insulating film is formed on at least one surface functioning as a bonding surface of at least one of the top wafer and the base wafer. FIG. 2(a) shows an example in which an insulating film is formed on the surface of the top wafer. However, the present invention is not limited to this embodiment. The insulating layer may be an oxide film, for example, that is formed by a known method such as hot oxidation or CVD method. The thickness of the insulating film thus formed is determined based on the desired device characteristics, and is not specifically limited. However, as set forth above, the method of manufacturing a bonded wafer of the present invention is effective for preventing the numerous void defects that are generated when bonding two wafers through a thin insulating film, or without the presence of an insulating film. Application of the present invention is effective when the thickness of the insulating film present at the bonding interface is 0 to 500 Angstroms, more effective when it is 0 to 200 Angstroms, and particularly effective when it is 0 to 50 Angstroms. The upper limit of the insulating film present at the bonding interface is not specifically limited; however, in practice, it may be about 3,000 Angstroms, by way of example.

When conducting the thinning step described below by an ion implantation separation method, as shown in FIG. 2(b), light element ions (such as hydrogen ions, noble gas ions, or a mixture of hydrogen ions and noble gas ions) are implanted into the top wafer to form an ion implantation layer in the top wafer. Ion implantation may be conducted with a known ion implanter. The acceleration voltage during ion implantation may be set to 10 to 100 keV, for example. In terms of productivity, lower ion implantation levels are more desirable. However, an excessively low level renders separation difficult in the subsequent heat treatment. In light of these considerations, the ion implantation level can be set to 2 e¹⁶ to 1 e¹⁷/cm², preferably 5 e¹⁶ to 1 e⁷/cm², for example.

Next, as shown in FIG. 2(c), the top wafer is bonded to the base wafer. In the bonding step, the jig employed in common wafer bonding can be employed and bonding can be conducted at room temperature, for example. By pre-polishing the bonding surfaces of the two wafers to mirror finishes, the wafers can be adhered without employing an adhesive or the like. As set forth above, in Method I, in the bonding step, a top wafer and a base wafer in which the total number of particles having a size of equal to or greater than 0.20 micrometers on the two surfaces being bonded is equal to or less than a prescribed level set on the basis of the insulating film thickness present at the bonding interface are bonded. Thus, the occurrence of void defects can be reduced or prevented in the bonded wafer obtained.

The surfaces of the top wafer and the base wafer being bonded in the bonding step both desirably have a surface smoothness with a surface roughness root mean square (RMS) of equal to or less than 10 Angstroms. Thus, adhesion between the wafers in the binding step can be strengthened. The surface roughness RMS is desirably equal to or less than 5 Angstroms. The lower limit of the surface roughness RMS is not specifically limited, but by way of example, may be about 0.1 Angstroms. The surface roughness RMS is an RMS value determined by measurement of a 10 micrometers×10 micrometers area by atomic force microscopy (AFM).

Following the bonding step, the top wafer is thinned. The thinning step can be conducted by ion implantation separation method, grinding, or the like. Use of the ion implantation separation method is desirable when highly adjusting the thickness of the remaining top wafer to thin the top wafer. When employing the ion implantation separation method, ion implantation can be conducted prior to the above-described bonding step and the wafer can be heat treated after the bonding step to permit the separation of a portion of the top wafer at the ion implantation layer as boundary (see FIG. 2(d)). The heat treatment is generally conducted at a temperature of equal to or higher than 300° C., preferably 350 to 500° C. When the temperature of the heat treatment falls within the stated range, bubbles can be generated in the ion implantation layer, and by causing the bubbles to form a continuous layer, separation can be caused at the ion implantation layer as boundary. The heat treatment can be conducted for a period of 1 minute to 1 hour, for example; preferably, 1 to 30 minutes. The rate of temperature increase is 0.5 to 10° C./minute, for example; preferably 1 to 5° C./minute. The heat treatment can be conducted with a known heat treatment device.

As shown in FIG. 2(e), the surface on the top wafer side and the surface on the base wafer side of the bonded surface obtained can be polished to obtain a bonded wafer of desired thickness.

Each step of Method II will be described below.

Method II comprises selection of at least one combination of a top wafer and a base wafer from a top wafer lot comprised of plural top wafers and a base wafer lot comprising a plurality of base wafers. Further, in this step, when the total thickness of the insulating films present on the two surfaces to be bonded exceeds 1,000 Angstroms, a combination of a top wafer and a base wafer in which the total number of particles having a size of equal to or greater than 0.20 micrometers on the two surfaces to be bonded is equal to or less than 0.014 particles/cm² is selected. When the total thickness of the insulating films present on the two surfaces to be bonded is equal to or less than 1,000 Angstroms, or no insulating film is present on the two surfaces to be bonded, a combination of a top wafer and a base wafer in which the total number of particles having a size of equal to or greater than 0.20 micrometers on the two surfaces to be bonded is equal to or less than 0.007 particles/cm² is selected. The wafer lot can be comprised of, for example, 50 to 100 wafers. Measurement of the particles on the surfaces of the wafers in the lot can be conducted by a known method using a device such as the SP-1, made by KLA Tencor. A combination of a top wafer and a base wafer in which the total number of particles having a size of equal to or greater than 0.20 micrometers on the two surfaces to be bonded is equal to or less than a prescribed level set on the basis of the thickness of the insulating films present at the bonding interface can be selected and the two selected wafers can be bonded to obtain a bonded wafer in which the generation of void defects is reduced or prevented. The preferred range of the total number of particles is stated above. Details of the bonding step and thinning step in Method II are also set forth above.

In Method II, a washing step may be performed in which at least a portion of top wafers and base wafers that have not been selected in the above selection are extracted and the extracted wafers are washed. This washing step can be used to reduce the particles on the surfaces of the wafers that are extracted. The washing step can be conducted by the above-described washing method. In this washing, adjustment is desirably conducted to achieve a surface roughness RMS of equal to or less than 10 Angstroms on the surfaces to be bonded. Thus, adhesion between wafers in the bonding step can be strengthened. The preferred range of the surface roughness RMS is as described above.

Subsequently, a re-selecting step may be performed in which at least one combination of a top wafer and a base wafer from wafers that have been subjected to the washing step, or wafers that have been subjected to the washing step and wafers that have not been subjected to the washing step is reselected. In this step, a combination of a top wafer and a base wafer in which the total number of particles having a size of equal to or greater than 0.20 micrometers on the two surfaces to be bonded is equal to or less than a prescribed value set on the basis of the thickness of the insulating film present at the bonding interface is selected. The preferred range of the total number of particles is as set forth above. The combination of the top wafer and base wafer selected in the above-described re-selecting step can be sequentially subjected to the bonding step and thinning step to mass produce bonded wafers in which the occurrence of voids is either reduced or prevented. Details of the above-described bonding step and thinning step are set forth above. By repeatedly conducting wafer extraction, wafer washing, the re-selecting step, the bonding step, and the thinning step, following the re-selecting step in the present invention, it is possible to mass produce bonded wafers employing a larger number of wafers from a single lot.

The present invention further relates to a bonded wafer manufactured by the above-described method.

As explained above, because the occurrence of void defects which compromises device characteristics can be reduced or prevented by the method of manufacturing a bonded wafer set forth in the present invention, the bonded wafer of the present invention obtained by this method is of high quality. Thus, it is possible to provide a high-quality device having good characteristics by employing the bonded wafer of the present invention.

### EXAMPLES

The present invention will be described in detail below based on examples. However, the present invention is not limited to the examples.

### Example 1

### Manufacturing an SOI Wafer (BOX Layer Thickness: 1,500 Angstroms)

Two silicon wafers were first prepared measuring 300 mm in diameter and 725 micrometers in thickness, having a specific resistance of 20 ohm·cm that had been sliced from a single silicon ingot grown by CZ method and doped with boron. Subsequently, these silicon wafers were polished to a mirror finish using methods known in the art. One of these wafers was then employed as the top wafer and the other as the base wafer.

Next, as shown in FIG. 2(a), an oxide film (BOX layer: embedded oxide film) was formed in the silicon wafer serving as top wafer. The oxide film was formed by placing the silicon wafer in an oxidation furnace and (wet) heat treating the silicon wafer for 20 minutes at 1,000° C. The oxide film was formed to a thickness of 1,500 Angstroms.

The top layer was washed with SC-1 (NH₄OH, H₂O₂, H₂O) washing solution for five minutes, rinsed with pure water, and dried. The washed silicon wafer with oxide film was then placed in the vacuum chamber of an ion implanter and rotation was begun. Then, implantation was conducted under conditions of 40 keV and 5.0 E 16/cm² with a hydrogen ion beam to form an ion implantation layer (see FIG. 2(b)).

The above steps were repeated to prepare a top wafer lot containing a plurality of top wafers and a base wafer lot containing a plurality of base wafers.

The particles adhering to the bonding surfaces of the top wafers in the top wafer lot and the base wafers in the base wafer lot were measured with an SP-1 made by KLA Tencor and the wafers were sorted by the total number of particles equal to or greater than 0.20 micrometers in size. A combination having a total of 0 particles (0 particle/cm²) to 20 particles (0.014 particle/cm²) of 0.20 micrometers or greater in size adhering to the bonding surfaces was selected and bonded. Following bonding, a heat treatment was conducted at 500° C. for 30 minutes to separate the top wafer at the boundary of the ion implantation layer, and the number of void defects following separation was measured by visual examination.

### Comparative Example 1

### Manufacturing an SOI Wafer (BOX Layer Thickness: 1,500 Angstroms)

A combination that had a total of equal to or more than 21 particles (equal to or more than 0.015 particle/cm²) of equal to or greater than 0.20 micrometers in size adhering to the bonding surfaces was selected from among the wafer lot prepared in Example 1 and bonded. Subsequently, the same separation treatment was performed as in Example 1 and the number of void defects following separation was determined by visual examination.

### Example 2

### Manufacturing an SOI Wafer (BOX Layer Thickness: 1,000 Angstroms)

With the exception that an oxide film 1,000 Angstroms in thickness was formed under oxidation conditions of 1,000° C.×10 minutes (wet) on a silicon wafer for use as top wafer, processing was conducted in the same manner as in Example 1 and a top wafer lot containing a plurality of top wafers and a base wafer lot containing a plurality of base wafers were prepared.

Combinations of wafers that had a total of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 2

### Manufacturing an SOI Wafer (BOX Layer Thickness: 1,000 Angstroms)

Combinations of wafers that had a total of equal to or greater than 11 particles (equal to or greater than 0.008 particle/cm²) of equal to or greater than 0.20 micrometers in size adhering to the bonding surfaces were selected from the wafer lots prepared in Example 2 and bonded. Subsequently, the same separation treatment was performed as in Example 1 and the number of void defects following separation was determined by visual examination.

### Example 3

### Manufacturing an SOI Wafer (BOX Layer Thickness: 500 Angstroms)

With the exception that an oxide film 500 Angstroms in thickness was formed under oxidation conditions of 950° C.×8 minutes (wet) on a silicon wafer for use as top wafer, processing was conducted in the same manner as in Example 1 and a top wafer lot containing a plurality of top wafers and a base wafer lot containing a plurality of base wafers were prepared.

In the same manner as in Example 2, combinations of wafers that had a total of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 3

### Manufacturing an SOI Wafer (BOX Layer Thickness: 500 Angstroms)

Combinations of wafers that had a total of equal to or more than 11 particles (equal to or more than 0.008 particle/cm²) of equal to or greater than 0.20 micrometers in size adhering to the bonding surfaces were selected from the wafer lots prepared in Example 3 and bonded. Subsequently, the same separation treatment was performed as in Example 1 and the number of void defects following separation was determined by visual examination.

### Example 4

### Manufacturing an SOI Wafer (BOX Layer Thickness: 300 Angstroms)

With the exception that an oxide film 300 Angstroms in thickness was formed under oxidation conditions of 850° C.×20 minutes (wet) on a silicon wafer for use as top wafer, processing was conducted in the same manner as in Example 1 and a top wafer lot containing a plurality of top wafers and a base wafer lot containing a plurality of base wafers were prepared.

In the same manner as in Example 2, combinations of wafers that had a total number of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 4

### Manufacturing an SOI Wafer (BOX Layer Thickness: 300 Angstroms)

Combinations of wafers that had a total number of equal to or more than 11 particles (equal to or more than 0.008 particle/cm²) of equal to or greater than 0.20 micrometers in size adhering to the bonding surfaces were selected from the wafer lots prepared in Example 4 and bonded. Subsequently, the same separation treatment was performed as in Example 1 and the number of void defects following separation was determined by visual examination.

### Example 5

### Manufacturing an SOI Wafer (BOX Layer Thickness: 200 Angstroms)

With the exception that an oxide film 200 Angstroms in thickness was formed under oxidation conditions of 850° C.×15 minutes (wet) on a silicon wafer for use as top wafer, processing was conducted in the same manner as in Example 1 and a top wafer lot containing a plurality of top wafers and a base wafer lot containing a plurality of base wafers were prepared.

In the same manner as in Example 2, combinations of wafers that had a total number of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 5

### Manufacturing an SOI Wafer (BOX Layer Thickness: 200 Angstroms)

Combinations of wafers that had a total number of equal to or more than 11 particles (equal to or more than 0.008 particle/cm²) of equal to or greater than 0.20 micrometers in size adhering to the bonding surfaces were selected from the wafer lots prepared in Example 5 and bonded. Subsequently, the same separation treatment was performed as in Example 1 and the number of void defects following separation was determined by visual examination.

### Example 6

### Manufacturing an SOI Wafer (BOX Layer Thickness: 100 Angstroms)

With the exception that an oxide film 100 Angstroms in thickness was formed under oxidation conditions of 850° C.×10 minutes (wet) on a silicon wafer for use as top wafer, processing was conducted in the same manner as in Example 1 and a top wafer lot containing a plurality of top wafers and a base wafer lot containing a plurality of base wafers were prepared.

In the same manner as in Embodiment 2, combinations of wafers that had a total number of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 6

### Manufacturing an SOI Wafer (BOX Layer Thickness: 100 Angstroms)

Combinations of wafers that had a total number of equal to or more than 11 particles (equal to or more than 0.008 particle/cm²) of equal to or greater than 0.20 micrometers in size adhering to the bonding surfaces were selected from the wafer lots prepared in Example 6 and bonded. Subsequently, the same separation treatment was performed as in Example 1 and the number of void defects following separation was determined by visual examination.

### Example 7

### Manufacturing an SOI Wafer (BOX Layer Thickness: 50 Angstroms)

With the exception that an oxide film 50 Angstroms in thickness was formed under oxidation conditions of 800° C.×40 minutes (dry) on a silicon wafer for use as top wafer, processing was conducted in the same manner as in Example 1 and a top wafer lot containing a plurality of top wafers and a base wafer lot containing a plurality of base wafers were prepared.

In the same manner as in Embodiment 2, combinations of wafers that had a total number of 0 particles (0 particle/cm²) to 10 particles (0.007 particle/cm²) of equal to or greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 7

### Manufacturing an SOI Wafer (BOX Layer Thickness: 50 Angstroms)

Combinations of wafers that had a total number of equal to or more than 11 particles (equal to or more than 0.008 particle/cm²) of equal to or greater than 0.20 micrometers in size adhering to the bonding surfaces were selected from the wafer lots prepared in Example 7 and bonded. Subsequently, the same separation treatment was performed as in Example 1 and the number of void defects following separation was determined by visual examination.

### Example 8

### Manufacturing a DSB Wafer (No BOX Layer)

With the exception that no processing was conducted to form an oxide flm on the silicon wafers serving as top wafers, processing was conducted in the same manner as in Example 1 and a top wafer lot containing a plurality of top wafers and a base wafer lot containing a plurality of base wafers were prepared.

In the same manner as in Example 2, combinations of wafers that had a total number of 0 particles (0 particle/cm²) to 10 particles (0.007 particle/cm²) of equal to ore greater than 0.20 micrometers in size adhering to the bonding surfaces were selected from these wafer lots and bonded. Subsequently, the same separation treatment was performed as in Example 1 and the number of void defects following separation was determined by visual examination.

### Comparative Example 8

### Manufacturing a DSB Wafer (No BOX Layer)

Combinations of wafers that had a total number of equal to or more than 11 particles (equal to or more than 0.008 particle/cm²) of equal to or greater than 0.20 micrometers in size adhering to the bonding surfaces were selected from the wafer lots prepared in Example 8 and bonded. Subsequently, the same separation treatment was performed as in Example 1 and the number of void defects following separation was determined by visual examination.

TABLE 1
Example 1 (BOX layer thickness: 1500 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 0 | 0, 3 | 0, 1 | 1, 4 | 0, 5 | 2.8 |
| Number of void defects | 0 | 0 | 0 | 0 | 0 | 0 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 8 | 0, 6 | 0, 8 | 0, 9 | 0, 8 | 9.4 |
| Number of void defects | 0 | 0 | 0 | 0 | 0 | 0 |
| | Total number of particles: | | | | | |
| | 11 to 20 particles | | | | | |
| | (0.008 to 0.014 particle/cm²) | | | | | |
| | a | b | c | d | e | Average |
| Number of particles (B, T) | 0, 13 | 0, 19 | 0, 15 | 0, 11 | 0, 15 | 14.6 |
| Number of void defects | 0 | 0 | 0 | 0 | 0 | 0 |

Comparative Example 1 (BOX layer thickness: 1500 Angstroms)

| | Total number of particles: | | | | | |
|---|---|---|---|---|---|---|
| | 21 to 50 particles | | | | | |
| | (0.015 to 0.035 particle/cm²) | | | | | |
| | a | b | c | d | e | Average |
| Number of particles (B, T) | 0, 22 | 0, 45 | 0, 32 | 0, 29 | 0, 30 | 31.6 |
| Number of void defects | 0 | 1 | 1 | 0 | 0 | 0.4 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 73 | 0, 60 | 1, 88 | 0, 59 | 0, 91 | 74.4 |
| Number of void defects | 2 | 1 | 3 | 1 | 3 | 2 |

*B = number of particles on the base wafer side,
T = number of particles on the top wafer side

TABLE 2
Example 2 (BOX layer thickness: 1000 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 2 | 0, 0 | 0, 0 | 0, 3 | 0, 2 | 1.4 |
| Number of void defects | 0 | 0 | 0 | 0 | 0 | 0 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 8 | 0, 9 | 0, 6 | 0, 7 | 0, 10 | 8 |
| Number of void defects | 0 | 0 | 0 | 0 | 0 | 0 |

Comparative Example 2 (BOX layer thickness: 1000 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 12 | 0, 14 | 0, 12 | 0, 20 | 0, 17 | 15 |
| Number of void defects | 0 | 1 | 0 | 3 | 1 | 1 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 31 | 0, 28 | 0, 40 | 0, 49 | 0, 35 | 36.6 |
| Number of void defects | 3 | 4 | 7 | 10 | 8 | 6.4 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 87 | 0, 67 | 0, 65 | 0, 94 | 0, 81 | 78.8 |
| Number of void defects | 5 | 2 | 3 | 7 | 4 | 4.2 |

*B = number of particles on the base wafer side,
T = number of particles on the top wafer side

TABLE 3
Example 3 (BOX layer thickness: 500 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 4 | 0, 2 | 0, 2 | 0, 2 | 0, 5 | 3 |
| Number of void defects | 0 | 0 | 0 | 0 | 0 | 0 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 7 | 0, 8 | 0, 8 | 1, 8 | 0, 6 | 7.6 |
| Number of void defects | 1 | 0 | 2 | 1 | 0 | 0.8 |

Comparative Example 3 (BOX layer thickness: 500 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 17 | 0, 16 | 1, 18 | 1, 15 | 0, 11 | 15.8 |
| Number of void defects | 2 | 6 | 7 | 5 | 1 | 4.2 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 1, 36 | 0, 44 | 0, 24 | 0, 39 | 0, 48 | 38.4 |
| Number of void defects | 12 | 15 | 8 | 16 | 18 | 13.8 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 54 | 0, 83 | 0, 78 | 1, 96 | 0, 80 | 78.4 |
| Number of void defects | 11 | 19 | 17 | 21 | 17 | 17 |

*B = number of particles on the base wafer side,
T = number of particles on the top wafer side

TABLE 4
Example 4 (BOX layer thickness: 300 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 0 | 0, 2 | 0, 3 | 0, 4 | 0, 4 | 2.6 |
| Number of void defects | 0 | 0 | 0 | 0 | 0 | 0 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 8 | 0, 6 | 0, 8 | 0, 7 | 0, 7 | 7.2 |
| Number of void defects | 1 | 0 | 0 | 1 | 0 | 0.4 |

Comparative Example 4 (BOX layer thickness: 300 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 15 | 0, 18 | 0, 13 | 0, 14 | 0, 14 | 14.8 |
| Number of void defects | 2 | 6 | 1 | 2 | 1 | 2.4 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 30 | 0, 39 | 0, 27 | 0, 48 | 1, 43 | 37.6 |
| Number of void defects | 13 | 11 | 12 | 20 | 14 | 14 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 81 | 0, 59 | 0, 78 | 0, 72 | 0, 66 | 71.2 |
| Number of void defects | 31 | 17 | 27 | 26 | 19 | 24 |

*B = number of particles on the base wafer side,
T = number of particles on the top wafer side

TABLE 5
Example 5 (BOX layer thickness: 200 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 1 | 0, 4 | 0, 2 | 0, 2 | 0, 2 | 2.2 |
| Number of void defects | 0 | 1 | 0 | 0 | 0 | 0.2 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 6 | 1, 7 | 1, 6 | 0, 6 | 0, 8 | 7 |
| Number of void defects | 0 | 1 | 1 | 0 | 0 | 0.4 |

Comparative Example 5 (BOX layer thickness: 200 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 13 | 0, 16 | 0, 13 | 0, 11 | 0, 19 | 14.4 |
| Number of void defects | 4 | 6 | 2 | 2 | 10 | 4.8 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 29 | 0, 38 | 0, 32 | 0, 48 | 0, 33 | 36 |
| Number of void defects | 18 | 25 | 24 | 28 | 21 | 23.2 |
| | Total number of particles: | | | | | |
| | 51 particles or more | | | | | |
| | (0.036 particle/cm² or more) | | | | | |
| | a | b | c | d | e | Average |
| Number of particles (B, T) | 1, 79 | 0, 90 | 1, 84 | 0, 67 | 0, 75 | 79.4 |
| Number of void defects | 66 | 73 | 68 | 46 | 51 | 60.8 |

*B = number of particles on the base wafer side,
T = number of particles on the top wafer side

TABLE 6
Example 6 (BOX layer thickness: 100 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 3 | 0, 3 | 0, 0 | 0, 0 | 1, 3 | 2 |
| Number of void defects | 0 | 1 | 0 | 0 | 1 | 0.4 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 6 | 0, 7 | 0, 7 | 0, 6 | 0, 8 | 6.8 |
| Number of void defects | 0 | 1 | 1 | 0 | 1 | 0.6 |

Comparative Example 6 (BOX layer thickness: 100 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 13 | 0, 12 | 0, 16 | 0, 11 | 0, 16 | 13.6 |
| Number of void defects | 4 | 4 | 11 | 3 | 8 | 6 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 42 | 1, 33 | 0, 37 | 0, 31 | 0, 29 | 34.6 |
| Number of void defects | 27 | 23 | 25 | 23 | 20 | 23.6 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 99 | 0, 81 | 0, 63 | 0, 77 | 0, 76 | 79.2 |
| Number of void defects | 82 | 70 | 59 | 65 | 63 | 67.8 |

*B = number of particles on the base wafer side,
T = number of particles on the top wafer side

TABLE 7
Example 7 (BOX layer thickness: 50 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 1, 3 | 0, 2 | 0, 3 | 0, 3 | 0, 3 | 3 |
| Number of void defects | 1 | 0 | 1 | 0 | 0 | 0.4 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 8 | 0, 6 | 1, 6 | 0, 10 | 0, 8 | 7.8 |
| Number of void defects | 2 | 1 | 1 | 4 | 1 | 1.8 |

Comparative Example 7 (BOX layer thickness: 50 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 20 | 0, 16 | 1, 17 | 1, 11 | 0, 14 | 16 |
| Number of void defects | 18 | 11 | 15 | 10 | 10 | 12.8 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 36 | 0, 22 | 0, 29 | 0, 49 | 0, 31 | 33.4 |
| Number of void defects | 31 | 19 | 25 | 35 | 30 | 28 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 84 | 1, 93 | 0, 80 | 0, 74 | 0, 87 | 83.8 |
| Number of void defects | 76 | 88 | 75 | 68 | 79 | 77.2 |

*B = number of particles on the base wafer side,
T = number of particles on the top wafer side

TABLE 8
Example 8 (BOX layer thickness: 0 Angstroms)

| | Total number of particles: | | | | | |
|---|---|---|---|---|---|---|
| | 0 to 5 particles | | | | | |
| | (0 to 0.004 particle/cm²) | | | | | |
| | a | b | c | d | e | Average |
| Number of particles (B, T) | 0, 3 | 0, 3 | 0, 2 | 0, 5 | 0, 2 | 3 |
| Number of void defects | 1 | 0 | 1 | 2 | 0 | 0.8 |
| | Total number of particles: | | | | | |
| | 6 to 10 particles | | | | | |
| | (0.005 to 0.007 particle/cm²) | | | | | |
| | a | b | c | d | e | Average |
| Number of particles (B, T) | 0, 9 | 0, 8 | 0, 8 | 0, 8 | 1, 8 | 8.4 |
| Number of void defects | 4 | 2 | 1 | 2 | 3 | 2.4 |

Comparative Example 8 (BOX layer thickness: 0 Angstroms)

| | Total number of particles: | | | | | |
|---|---|---|---|---|---|---|
| | 11 to 20 particles | | | | | |
| | (0.008 to 0.014 particle/cm²) | | | | | |
| | a | b | c | d | e | Average |
| Number of particles (B, T) | 0, 15 | 1, 15 | 0, 12 | 0, 17 | 0, 14 | 14.8 |
| Number of void defects | 14 | 14 | 9 | 17 | 1 | 11 |
| | Total number of particles: | | | | | |
| | 21 to 50 particles | | | | | |
| | (0.015 to 0.035 particle/cm²) | | | | | |
| | a | b | c | d | e | Average |
| Number of particles (B, T) | 0, 25 | 0, 21 | 0, 50 | 0, 43 | 1, 36 | 35.2 |
| Number of void defects | 24 | 20 | 40 | 35 | 36 | 31 |
| | Total number of particles: | | | | | |
| | 51 particles or more | | | | | |
| | (0.036 particle/cm² or more) | | | | | |
| | a | b | c | d | e | Average |
| Number of particles (B, T) | 0, 58 | 0, 88 | 0, 79 | 0, 98 | 0, 83 | 81.2 |
| Number of void defects | 54 | 83 | 73 | 95 | 80 | 77 |

*B = number of particles on the base wafer side,
T = number of particles on the top wafer side

From the results in Table 1, it will be understood that when two wafers were bonded through a relatively thick 1,500 Angstrom oxide film and the total number of particles of equal to or greater than 0.20 micrometers in size exceeded 20 particles (0.014 particle/cm²), there was a marked generation of void defects. Thus, in this case, bonded wafers of high quality in which the occurrence of void defects was either reduced or prevented were obtained by selecting a combination of top wafer and base wafer having a total of equal to or fewer of 20 particles (equal to or less than 0.014 particle/cm²) of equal to or greater than 0.20 micrometers in size on the two surfaces being bonded. From the results in Tables 2 to 8, it will be further understood that when two wafers were bonded through an oxide film with a thickness of equal to or less than 1,000 Angstroms, or were directly bonded without the presence of an oxide film, and the total number of particles of equal to or greater than 0.20 micrometers in size exceeded 10 particles (0.007 particle/cm²), there was marked generation of void defects. Thus, in this case, bonded wafers of high quality in which the occurrence of void defects was either reduced or prevented were obtained by selecting a combination of top wafer and base wafer having a total of equal to or fewer than 10 particles (equal to or less than 0.007 particle/cm²) of equal to or greater than 0.20 micrometers in size on the two surfaces being bonded. Moreover, the results of Examples 7 and 8 show that the occurrence of void defects could be particularly effectively reduced in case of an oxide film thickness of 0 to 50 Angstroms and a total of equal to or fewer than 5 particles (equal to or less t than 0.004 particle/cm²).

As set forth above, when conventional methods are employed, void defect occurrence is marked when two wafers are bonded through a relatively thin oxide film or bonded without the presence of an oxide film. By contrast, the above results show that the present invention can provide a high-quality bonded wafer in which the occurrence of void defects is effectively reduced even in such cases.

According to the present invention, a high-quality bonded wafer can be provided.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

Unless otherwise stated, a reference to a compound or component includes the compound or component by itself, as well as in combination with other compounds or components, such as mixtures of compounds.

As used herein, the singular forms “a,”, “an,” and “the” include the plural reference unless the context clearly dictates otherwise.

Except where otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not to be considered as an attempt to limit the application of the doctrine of equivalents to the scope of the claims, each numerical parameter should be construed in light of the number of significant digits and ordinary rounding conventions.

Additionally, the recitation of numerical ranges within this specification is considered to be a disclosure of all numerical values and ranges within that range. For example, if a range is from about 1 to about 50, it is deemed to include, for example, 1, 7, 34, 46.1, 23.7, or any other value or range within the range.

What is claimed is:

1. A method of manufacturing a bonded wafer comprising:
bonding a top wafer and a base wafer to form a bonded wafer, and
thinning the top wafer comprised in the bonded wader,
wherein, in said bonding,
when bonding the top wafer through an insulating film exceeding about 1,000 Angstroms in thickness to the base wafer, a top wafer and a base wafer are bonded wherein the total number of particles having a size of equal to or greater than about 0.20 micrometers present on the two surfaces being bonded is equal to or less than about 0.014 particles/cm²; and
when bonding the top wafer through an insulating film having a thickness of equal to or less than about 1,000 Angstroms to the base wafer, or with no insulating film present between the top wafer and the base wafer, a top wafer and a base wafer are bonded wherein the total number of particles having a size of equal to or greater than about 0.20 micrometers present on the two surfaces being bonded is equal to or less than about 0.007 particles/cm².

2. The method of manufacturing a bonded wafer of claim 1, wherein, in said bonding, the top wafer is bonded to the base wafer through an insulating film having a thickness of equal to or less than about 500 Angstroms or with no insulating film present between the top wafer and the base wafer.

3. The method of manufacturing a bonded wafer of claim 1, wherein both of the two surfaces being bonded in said bonding have a surface roughness, RMS, of equal to or less than about 10 Angstroms.

4. The method of manufacturing a bonded wafer of claim 1, wherein said thinning is conducted by, prior to said bonding, implanting light element ions into a top wafer to form an ion implantation layer in the top wafer, and following said bonding, subjecting the bonded wafer to heat treatment to separate a portion of the top wafer from the bonded wafer at the ion implantation layer as boundary.

5. A method of manufacturing a bonded wafer comprising:
selecting at least one combination of a top wafer and a base wafer from a top wafer lot comprising a plurality of top wafers and a base wafer lot comprising a plurality of base wafers,
bonding the selected combination of a top wafer and a base wafer to form a bonded wafer, and
thinning the top wafer comprised in the bonded wafer,
wherein, in said selecting,
when the total thickness of an insulating film present on the two surfaces to be bonded exceeds about 1,000 Angstroms, a combination of a top wafer and a base wafer in which the total number of particles having a size of equal to or greater than about 0.20 micrometers on the two surfaces to be bonded is equal to or less than about 0.014 particles/cm² is selected; and
when the total thickness of an insulating film present on the two surfaces to be bonded is equal to less than about 1,000 Angstroms, or when no insulating film is present on the two surfaces to be bonded, a combination of a top wafer and a base wafer in which the total number of particles having a size of equal to or greater than about 0.20 micrometers on the two surfaces to be bonded is equal to or less than about 0.007 particles/cm² is selected.

6. The method of manufacturing a bonded wafer of claim 5, which further comprises:
extracting at least a portion of top wafers and base wafers that have not been selected in said selecting,
washing the extracted wafers, and
re-selecting at least one combination of a top wafer and a base wafer from wafers that have been subjected to said washing, or wafers that have been subjected to said washing and wafers that have not been subjected to said washing,
bonding the combination of a top wafer and a base wafer selected in said re-selecting to form a bonded wafer, and
thinning the top wafer comprised in the bonded wafer,
wherein, in said re-selecting,
when the total thickness of an insulating film present on the two surfaces to be bonded exceeds about 1,000 Angstroms, a combination of a top wafer and a base wafer in which the total number of particles having a size of equal to or greater than about 0.20 micrometers on the two surfaces to be bonded is equal to or less than about 0.014 particles/cm² is selected; and
when the total thickness of an insulating film present on the two surfaces to be bonded is equal to less than about 1,000 Angstroms, or when no insulating film is present on the two surfaces to be bonded, a combination of a top wafer and a base wafer in which the total number of particles having a size of equal to or greater than about 0.20 micrometers on the two surfaces to be bonded is equal to or less than about 0.007 particles/cm² is selected.

7. The manufacturing method of a bonded wafer of claim 6, wherein said washing is conducted so as to obtain a washed wafer comprising a surface to be bonded when the washed wafer is subjected to said bonding having a surface roughness, RMS, of equal to or less than about 10 Angstroms.

8. The method of manufacturing a bonded wafer of claim 5, wherein, in said bonding, the top wafer is bonded to the base wafer through an insulating film having a thickness of equal to or less than about 500 Angstroms or with no insulating film present between the top wafer and the base wafer.

9. The method of manufacturing a bonded wafer of claim 5, wherein both of the two surfaces being bonded in said bonding have a surface roughness, RMS, of equal to or less than about 10 Angstroms.

10. The method of manufacturing a bonded wafer of claim 5, wherein said thinning is conducted by, prior to said bonding, implanting light element ions into a top wafer to form an ion implantation layer in the top wafer, and following said bonding, subjecting the bonded wafer to heat treatment to separate a portion of the top wafer from the bonded wafer at the ion implantation layer as boundary.

11. A bonded wafer manufactured by the method of claim 1.

12. A bonded wafer manufactured by the method of claim 5.
